(19) United States
(12) Patent Application Publication
(10) Pub. No.: US 2026/0090258 A1
(43) Pub. Date: Mar. 26, 2026

(54) DISPLAY DEVICE AND ELECTRONIC DEVICE INCLUDING THE SAME

(71) Applicant: Samsung Display Co., Ltd., Yongin-Si (KR)

(72) Inventors: HYANGYUL KIM, Yongin-si (KR); JAEHONG KIM, Yongin-si (KR); CHANGHAN LEE, Yongin-si (KR); JIWON JUNG, Yongin-si (KR)

(21) Appl. No.: 19/199,421

(22) Filed: May 6, 2025

(30) Foreign Application Priority Data
Sep. 25, 2024 (KR) 10-2024-0129670

(51) Int. Cl. H10K 59/80; H10K 59/126

(52) U.S. Cl. CPC H10K 59/8792; H10K 59/126

(57) ABSTRACT

A display device includes a display panel including at least one light-emitting element and including a first side and a second side having a length smaller than a length of the first side, a polarizing film including an absorption axis parallel to the second side of the display panel and a transmission axis, a first phase retardation film including a first optical axis which intersects the transmission axis of the polarizing film and the absorption axis of the polarizing film, and a light control film including a plurality of light-blocking patterns spaced apart from each other and a plurality of light-transmitting patterns disposed between the plurality of light-blocking patterns.

### CROSS-REFERENCE TO RELATED APPLICATION(S)

This application claims priority under 35 U.S.C. § 119 to Korean Patent Application No. 10-2024-0129670, filed on Sep. 25, 2024, which is hereby incorporated by reference for all purposes as if fully set forth herein.

### BACKGROUND

### 1. Field

Embodiments relate to a display device. More particularly, embodiments relate to the display device that adjusts a viewing angle.

### 2. Description of the Related Art

A display device is a device that displays an image to provide visual information to a user. The display device may be multimedia devices such as televisions, mobile phones, tablet computers, navigation systems, and game consoles. Since the display device displays an image using light, the display quality may be improved through light utilization efficiency improvement or light control.

In order to provide the display device with improved display quality, a polarizing member that includes a polarizing film and a phase delay film may be used. In addition, a light control film for adjusting a viewing angle may be used to implement a private mode of the display device.

### SUMMARY

Embodiments provide a display device with improved bubble defects.

A display device according to an embodiment includes a display panel including at least one light-emitting element and including a first side and a second side having a length shorter than a length of the first side, a polarizing film disposed on the display panel and including an absorption axis parallel to the second side of the display panel and a transmission axis which intersects the absorption axis, a first phase retardation film disposed between the display panel and the polarizing film in a cross-sectional view and including a first optical axis which intersects the transmission axis of the polarizing film and the absorption axis of the polarizing film in a plan view, and a light control film disposed on the polarizing film and including a plurality of light-blocking patterns spaced apart from each other and a plurality of light-transmitting patterns disposed between the plurality of light-blocking patterns.

In an embodiment, the first phase retardation film may retard a phase of light transmitting the first phase retardation film by ¼ wavelength.

In an embodiment, an angle between the first optical axis and the absorption axis may be about 40° or more and about 50° or less in a plan view.

In an embodiment, a thickness of the first phase retardation film may be about 3 μm or more and about 5 μm or less.

In an embodiment, the display device may further include a second phase retardation film disposed between the polarizing film and the light control film in a cross-sectional view, and including a second optical axis which intersects the transmission axis of the polarizing film and the absorption axis of the polarizing film in a plan view.

In an embodiment, a stretched direction of the light control film may be vertical to the absorption axis of the polarizing film.

In an embodiment, each of the light-blocking patterns of the light control film may be spaced apart from each other in a direction parallel to the second side of the display panel, and each of the light-blocking patterns of the light control film may extend along a direction parallel to the first side of the display panel.

In an embodiment, the second phase retardation film may retard a phase of light transmitting the second phase retardation film by ½ wavelength.

In an embodiment, an angle between the second optical axis and the absorption axis may be about 40° or more and about 50° or less in a plan view.

In an embodiment, a thickness of the second phase retardation film may be about 1 μm or more and about 3 μm or less.

In an embodiment, a stretched direction of the light control film may be parallel to the absorption axis of the polarizing film.

In an embodiment, each of the light-blocking patterns of the light control film may be spaced apart from each other in a direction parallel to the first side of the display panel, and each of the light-blocking patterns of the light control film may extend along a direction parallel to the second side of the display panel.

A display device according to an embodiment includes a display panel including at least one light-emitting element, and including a first side extending along a first direction and a second side extending along a second direction which intersects with the first direction and having a length shorter than a length of the first side, a polarizing film disposed on the display panel and including a transmission axis parallel to the first direction and an absorption axis parallel to the second direction, a first phase retardation film disposed between the display panel and the polarizing film in a cross-sectional view and including a first optical axis which intersects with the transmission axis of the polarizing film and the absorption axis of the polarizing film, and a second phase retardation film disposed on the polarizing film and including a second optical axis which intersects with the transmission axis of the polarizing film and the absorption axis of the polarizing film.

In an embodiment, the first phase retardation film may retard a phase of light transmitting the first phase retardation film by ¼ wavelength, and the second phase retardation film may retard a phase of light transmitting the second phase retardation film by ½ wavelength.

In an embodiment, an angle between the first optical axis and the absorption axis may be about 40° or more and about 50° or less in a plan view, and an angle between the second optical axis and the absorption axis may be about 40° or more and about 50° or less, in a plan view.

In an embodiment, a stretched direction of the polarizing film may be parallel to the second side of the display panel.

In an embodiment, the display device may further include a light control film disposed on the second phase retardation film.

In an embodiment, the light control film may include a plurality of light-blocking patterns extending along the first direction, and spaced apart from each other in the second direction and a plurality of light-transmitting patterns disposed between the plurality of light-blocking patterns, and a stretched direction of the light control film may be parallel to the first side of the display panel.

A display device according to an embodiment includes a display panel including at least one light-emitting element and including a first side and a second side having a length shorter than a length of the first side, a polarizing film disposed on the display panel and including an absorption axis parallel to the second side of the display panel and a transmission axis which intersects with the absorption axis, a phase retardation film disposed between the display panel and the polarizing film in a cross-sectional view and including a first optical axis which intersects with the transmission axis of the polarizing film and the absorption axis of the polarizing film in a plan view, and a light control film disposed on the polarizing film and including a stretched direction parallel to the absorption axis of the polarizing film.

In an embodiment, the phase retardation film may retard a phase of light transmitting the phase retardation film by ¼ wavelength.

An electronic device according to an embodiment includes a display device and a processor configured to drive the display device. The display device may include a display panel including at least one light-emitting element and including a first side and a second side having a length shorter than a length of the first side, a polarizing film disposed on the display panel and including an absorption axis parallel to the second side of the display panel and a transmission axis which intersects the absorption axis, a first phase retardation film disposed between the display panel and the polarizing film in a cross-sectional view and including a first optical axis which intersects the transmission axis of the polarizing film and the absorption axis of the polarizing film in a plan view, and a light control film disposed on the polarizing film, and including a plurality of light-blocking patterns spaced apart from each other and a plurality of light-transmitting patterns disposed between the plurality of light-blocking patterns.

In an embodiment, the electronic device may be part of one of a smart phone, a television, a mobile phone, a video phone, a smart pad, a smart watch, a tablet PC, a vehicle display, a computer monitor, a notebook computer, a head-mounted display device, a television, a monitor, a notebook computer, a tablet and an automobile.

In a display device according to embodiments of the present disclosure, an absorption axis of a polarizing film may be parallel to a short side of a display panel. Accordingly, when heat is applied to the display device, the polarizing film does not shrink along a long side of the display panel, thereby preventing a phenomenon of bubbles being generated between a window layer and a light control film. Accordingly, a reliability of the display device may be improved.

In addition, in the display device, a second phase retardation film which retards a phase of a transmitted light by ½ wavelength may be disposed between the polarizing film and a light control film in a cross-sectional view. Accordingly, even if the absorption axis of the polarizing film and a stretched direction of the light control film do not coincide with each other, an emitted light may be linearly polarized to coincide with the axis of the polarizing glasses, thereby providing an image which may be viewed by a user wearing a polarizing glasses. Accordingly, a private mode of the display device may be easily implemented.

### BRIEF DESCRIPTION OF THE DRAWINGS

Illustrative, non-limiting embodiments will be more clearly understood from the following detailed description in conjunction with the accompanying drawings

FIG. 1 is a perspective view illustrating a display device according to an embodiment of the present disclosure.

FIG. 2 is an exploded perspective view illustrating an example of the display device of FIG. 1.

FIG. 3 is an exploded perspective view illustrating another example of the display device of FIG. 1.

FIG. 4 is an exploded perspective view illustrating an optical functional layer of FIG. 1.

FIG. 5 is a cross-sectional view explaining a function of a light control film of FIG. 4.

FIG. 6 is a plan view explaining an example of the angle between an optical axis of each of a first phase delaying layer and the second phase delaying layer of FIG. 4 and a transmission axis of the polarizing film.

FIG. 7 is a plan view explaining another example of the angle between an optical axis of each of a first phase delaying layer and the second phase delaying layer of FIG. 4 and a transmission axis of the polarizing film.

FIG. 8 is a cross-sectional view illustrating a cross-section taken along the line I-I′ of FIG. 1.

FIG. 9 is a cross-sectional view illustrating an enlarged view of area A of FIG. 8.

FIG. 10 is a view for explaining an example of a function of the optical functional layer of FIG. 1.

FIG. 11 is a view for explaining another example of a function of the optical functional layer of FIG. 1.

FIG. 12 is a perspective view illustrating a display device according to another embodiment of the present disclosure.

FIG. 13 is an exploded perspective view illustrating an example of the display device of FIG. 12.

FIG. 14 is an exploded perspective view illustrating another example of the display device of FIG. 12.

FIG. 15 is an exploded perspective view illustrating an optical functional layer of FIG. 12.

FIG. 16 is a view for explaining an example of a function of the optical functional layer of FIG. 12.

FIG. 17 is a view for explaining another example of a function of the optical functional layer of FIG. 12.

FIG. 18 is a block diagram illustrating an electronic device according to an embodiment of the present disclosure.

FIG. 19 is a view for explaining an example of the electronic device of FIG. 18 implemented as a smartphone.

FIG. 20 is a view for explaining an example of the electronic device of FIG. 18 implemented as a television.

FIG. 21 is a view illustrating an example of the electronic device of FIG. 18 implemented as an automobile.

FIG. 22 is a view illustrating an interior of the automobile of FIG. 21.

FIGS. 23 and 24 are views for explaining an effect of the display device included in the automobile of FIG. 21.

### DETAILED DESCRIPTION OF THE EMBODIMENTS

The present disclosure now will be described more fully hereinafter with reference to the accompanying drawings, in which embodiments of the present disclosure are shown. The present disclosure may, however, be embodied in many different forms and should not be construed as limited to the embodiments set forth herein.

Rather, these embodiments are provided so that this disclosure will be thorough and complete, and will fully convey the scope of the present disclosure to those skilled in the art. Like reference numerals refer to like elements throughout.

It will be understood that, although the terms first, second, third, and the like. may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer or section without departing from the teachings of the present disclosure.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein may be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Hereinafter, a display device in accordance with embodiments will be described in more detail with reference to the accompanying drawings. The same reference numerals are used for the same components in the drawings, and redundant descriptions of the same components will be omitted.

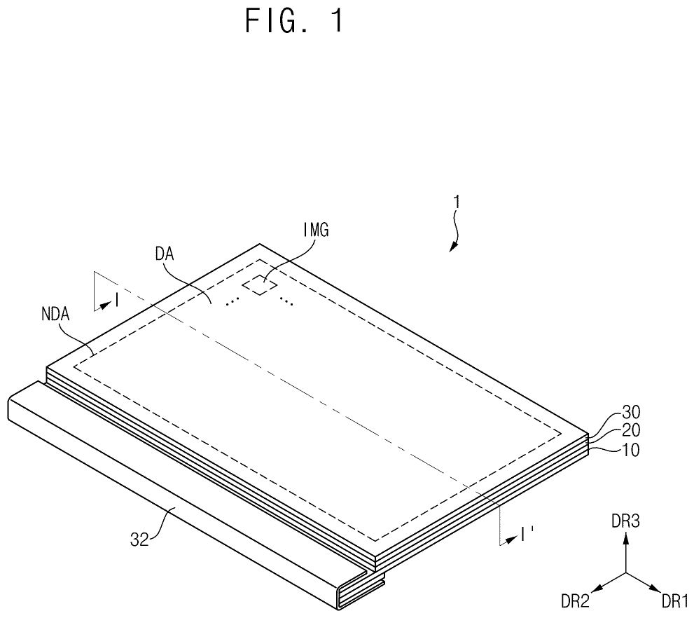

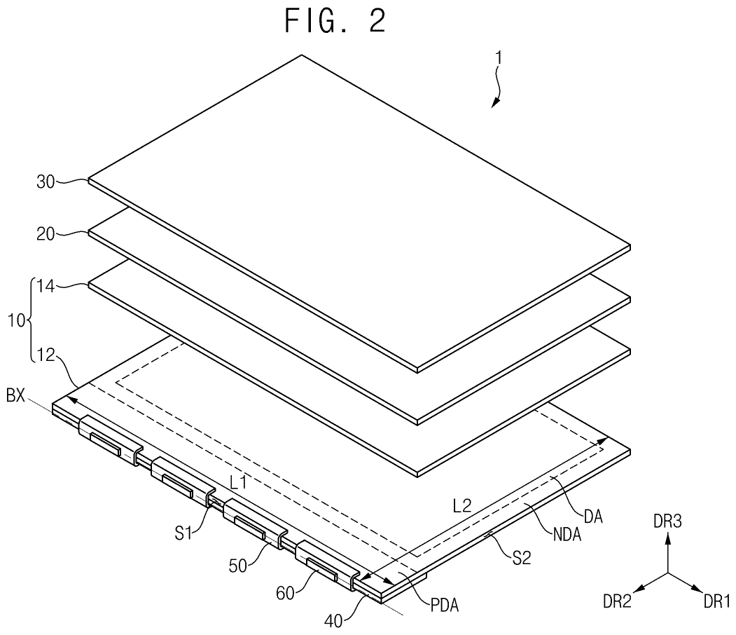

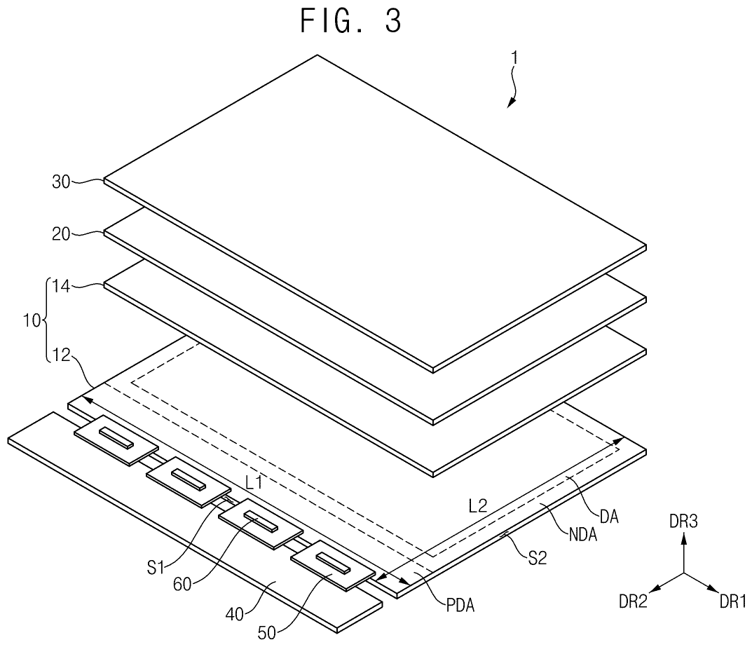

FIG. 1 is a perspective view illustrating a display device according to an embodiment of the present disclosure. FIG. 2 is an exploded perspective view illustrating an example of the display device of FIG. 1. FIG. 3 is an exploded perspective view illustrating another example of the display device of FIG. 1. For example, FIG. 2 is an exploded perspective view illustrating a state in which the display device 1 is folded in a pad area PDA. For example, FIG. 3 is an exploded perspective illustrating a state in which the display device 1 is unfolded in the pad area PDA.

Referring to FIGS. 1, 2, and 3, the display device 1 according to an embodiment of the present disclosure may include a display panel 10, an optical functional layer 20, a window layer 30, a driving cover member 32, a first circuit board 40, a second circuit board 50, and a driving member 60. The display panel 10 may include a display element layer 12 and an encapsulation substrate 14. The display device 1 may include a display area DA, a non-display area NDA, and the pad area PDA.

In this specification, a plane may be defined by a first direction DR1 and a second direction DR2 which intersects the first direction DR1. For example, the second direction DR2 may be perpendicular to the first direction DR1 in a plan view. In addition, a third direction DR3 may be perpendicular to the plane.

The display area DA may be an area generating light or displaying an image by controlling a transmittance of light provided from a light source. At least one pixel emitting light may be disposed in the display area DA. The pixel may be disposed in a plural numbers within the display area DA. For example, the pixel may be disposed in a first direction DR1 and a second direction DR2 within the display area DA in a matrix form. The pixel may emit light. In an embodiment, an image IMG may be displayed within the display area DA by the pixels. For example, the image IMG may be displayed within the display area DA by light emitted from the pixels.

The pixel may include sub-pixels emitting light of different colors. For example, the sub-pixels may include first, second, and third sub-pixels, and the first sub-pixel may emit first color of light, the second sub-pixel may emit second color of light, and the third sub-pixel may emit third color of light. In an embodiment, the first color of light may be red, the second color of light may be green, and the third color of light may be blue. However, a color of light emitted by each of the sub-pixels included in the pixel according to the embodiments of the present disclosure may not be limited thereto, and may emit light having various colors such as magenta, cyan, and yellow.

The non-display area NDA may surround at least a portion of the display area DA. For example, the non-display area NDA may entirely surround the display area DA in a plan view. The non-display area NDA may be defined as an area that does not emit light and does not generate an image. A driver for driving the pixel may be disposed in the non-display area NDA. The driver may provide a signal and/or voltage to the pixel. For example, the driver may include a scan driver, a light-emitting driver and the like.

The pad area PDA may be disposed on one side of the display area DA to be spaced apart from the display area DA. For example, the pad area PDA may be spaced apart from the one side of the display area DA in a second direction DR2. In an embodiment, the pad area PDA may be spaced apart from the display area DA in the second direction DR2 with a non-display area NDA disposed therebetween. That is, the non-display area NDA may be disposed between the pad area PDA and the display area DA. Pad electrodes electrically connected to a data driver that applies a data signal to the pixel may be disposed in the pad area PDA.

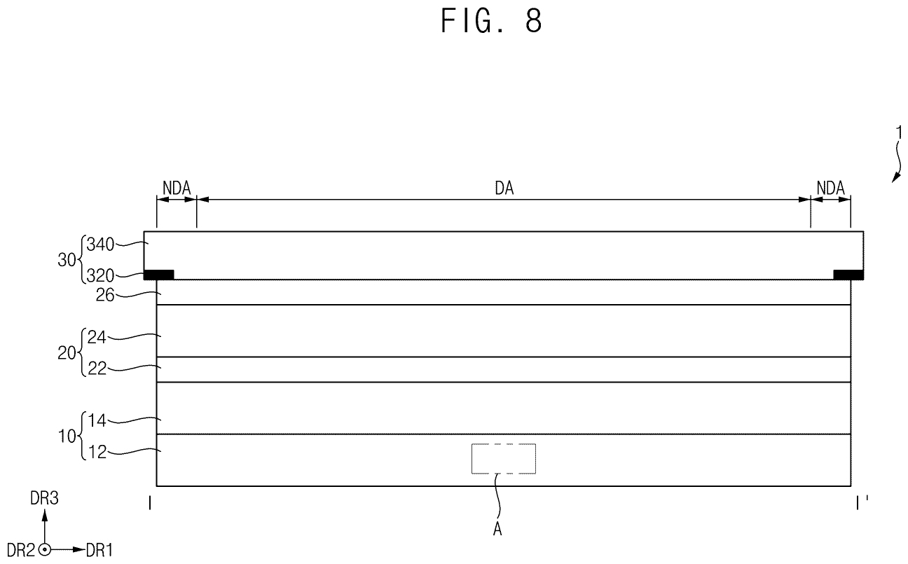

As the display device 1 includes a display area DA, a non-display area NDA, and a pad area PDA, the display panel 10 may include a display area DA, a non-display area NDA, and a pad area PDA. The display panel 10 may include the pixels. For example, the display element layer 12 disposed at a lower portion of the display panel 10 may include the pixel. The encapsulation substrate 14 disposed at an upper portion of the display panel 10 may cover the display element layer 12. For example, the encapsulation substrate 14 may protect the display element layer 12 from external foreign substances or impact. The display element layer 12 and the encapsulation substrate 14 will be described in detail with reference to FIGS. 7 and 8.

The display panel 10 may include a first side S1 and a second side S2. For example, a length of the first side S1 in the first direction DR1 may be defined as a first length L1, and a length of the second side S2 in the second direction DR2 may be defined as a second length L2. In an embodiment, the first length L1 of the first side S1 may be greater than the second length L2 of the second side S2. In other words, the first side S1 may be a long side of the display panel 10 and the second side S2 may be a short side of the display panel 10. Specifically, the display panel 10 may have a long side parallel to the first direction DR1, and a short side parallel to the second direction DR2.

The optical functional layer 20 may be disposed on the display panel 10. For example, the optical functional layer 20 may be disposed on the encapsulation substrate 14. In an embodiment, the optical functional layer 20 may be disposed on the display area DA and the non-display area NDA of the display panel 10. In an embodiment, the optical functional layer 20 may not be disposed in the pad area PDA of the display panel 10. However, an arrangement of the optical functional layer 20 according to embodiments of the present disclosure may not be necessarily limited thereto, and a portion of the optical functional layer 20 may be disposed in the pad area PDA of the display panel 10.

In an embodiment, since the display panel 10 has the first side S1 and the second side S2, the optical functional layer 20 may have a long side parallel to the first direction DR1 and a short side parallel to the second direction DR2.

The window layer 30 may be disposed on the optical functional layer 20. In an embodiment, the window layer 30 may be disposed on the display area DA and the non-display area NDA of the display panel 10. In an embodiment, the window layer 30 may not be disposed in the pad area PDA of the display panel 10. However, the arrangement of the window layer 30 according to embodiments of the present disclosure may not be necessarily limited thereto, and a portion of the window layer 30 may be disposed in the pad area PDA of the display panel 10.

In an embodiment, since the display panel 10 has the first side S1 and the second side S2, the window layer 30 may have a long side parallel to the first direction DR1 and a short side parallel to the second direction DR2.

The driving cover member 32 may be disposed in the pad area PDA of the display panel 10. For example, the driving cover member 32 may cover the pad area PDA of the display panel 10. Specifically, the driving cover member 32 may cover a portion of the display panel 10, the first circuit board 40, the second circuit board 50, and the driving member 60 located in the pad area PDA. Accordingly, the driving cover member 32 may protect the driving member 60 from external foreign substances or impact.

In an embodiment, the driving cover member 32 may be disposed in the non-display area NDA of the display panel 10. For example, the driving cover member 32 may come into contact with a portion of the sealing substrate 14 disposed on the non-display area NDA. However, an arrangement of the driving cover member 32 according to the embodiments of the present disclosure may not be necessarily limited thereto.

The first circuit board 40 may be disposed on a lower portion of the display panel 10. In an embodiment, a timing controller, a power voltage generator, and the like may be disposed on the first circuit board 40. Specifically, the first circuit board 40 may generate a scan control signal, a data control signal, and image data using an image signal and a plurality of timing signals received from the timing controller and the power voltage generator. However, the first circuit board 40 according to embodiments of the present disclosure may not be necessarily limited thereto, and the first circuit board 40 may be electrically connected to an external electronic component or electronic device including a timing controller, a power voltage generator, and the like. In this case, the electronic component or electronic device may be covered by a driving cover member 32. In an embodiment, the first circuit board 40 may include at least one metal wiring layer and at least one insulating layer.

In an embodiment, the first circuit board 40 may be a printed circuit board (PCB). In an embodiment, since the display panel 10 has the first side S1 and the second side S2, the first circuit board 40 may have a long side parallel to the first direction DR1 and a short side parallel to the second direction DR2. In an embodiment, a length of the long side of the first circuit board 40 may be smaller than the first length L1 of the first side S1 of the display panel 10. However, the length of the long side of the first circuit board 40 according to embodiments of the present disclosure may not be necessarily limited thereto, and the length of the long side of the first circuit board 40 may be equal to the first length L1 of the first side S1 of the display panel 10 or may be greater than the first length L1 of the first side S1.

The second circuit board 50 may be electrically connected to the first circuit board 40. For example, the second circuit board 50 may be in contact with the first circuit board 40. The second circuit board 50 may overlap a portion of each of the first circuit board 40 and the display panel 10 in a plan view. For example, the second circuit board 50 may be electrically connected to the pad electrodes disposed on the pad area PDA of the display panel 10. Accordingly, the second circuit board 50 may electrically connect the display panel 10, the first circuit board 40, and the driving member 60 to each other.

In an embodiment, the second circuit board 50 may be bent from an upper surface of the display panel 10 toward a lower surface. For example, the second circuit board 50 may be bent from an upper surface of the display panel 10 to a lower surface of the display panel 10 along the bending axis BX extending parallel to the first direction DR1. Accordingly, the first circuit board 40 and the display panel 10 disposed at a lower portion of the display panel 10 may be electrically connected to each other through the bent second circuit board 50. However, the first circuit board 40 and the second circuit board 50 according to the embodiments of the present disclosure may not be necessarily limited thereto, and each of the first circuit board 40 and the second circuit board 50 may be disposed in a same plane as the display panel 10 is disposed.

In an embodiment, the second circuit board 50 may be a flexible printed circuit board (FPCB). However, the types of each of the first circuit board 40 and the second circuit board 50 according to the embodiments of the present disclosure may not be necessarily limited thereto.

The driving member 60 may apply a data signal to the pixels. For example, the driving member 60 may transmit the data signal to the pixels based on signals generated by the first circuit board 40. The driving member 60 may be disposed on the second circuit board 50. However, an arrangement of the driving member 60 according to embodiments of the present disclosure may not be necessarily limited thereto, and the driving member 60 may also be disposed in the pad area PDA of the display panel 10.

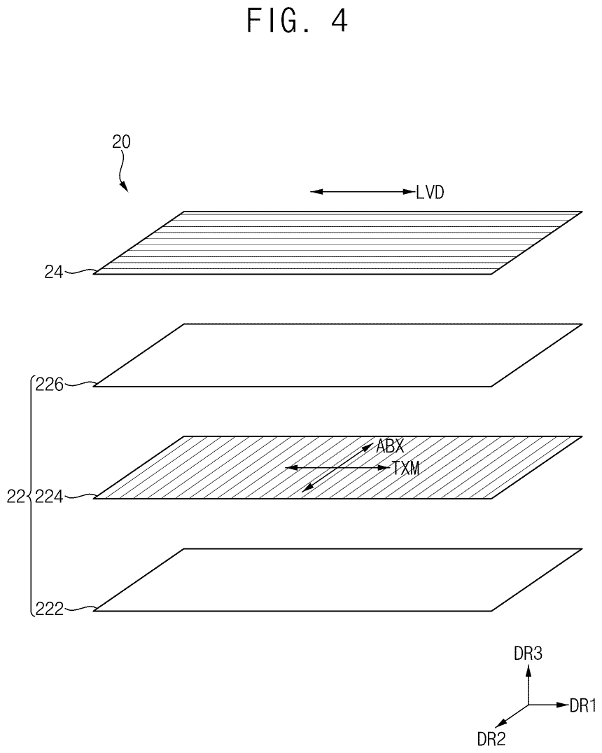

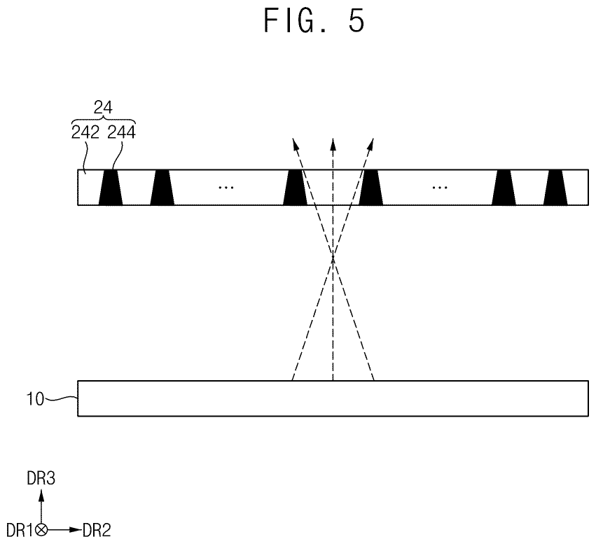

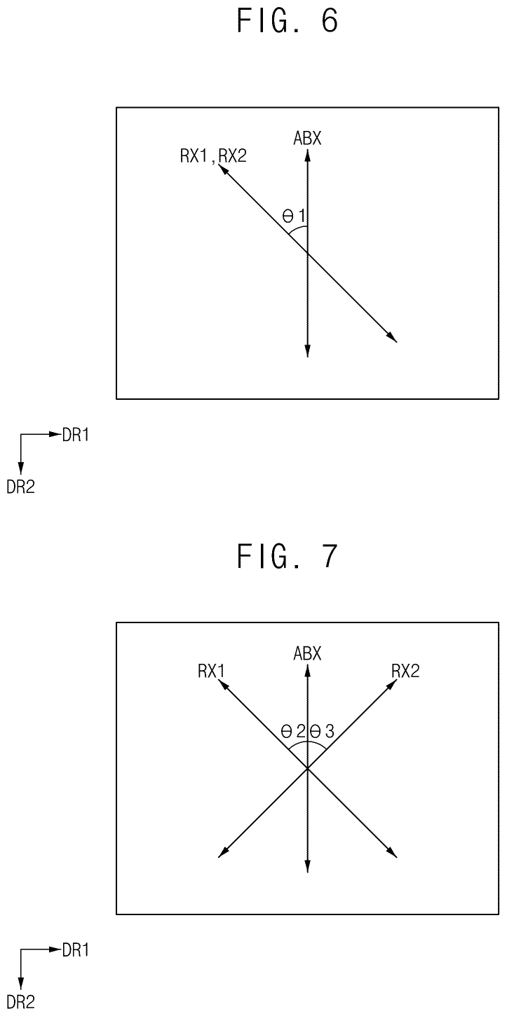

FIG. 4 is an exploded perspective view illustrating an optical functional layer of FIG. 1. FIG. 5 is a cross-sectional view explaining a function of a light control film of FIG. 4. FIG. 6 is a plan view explaining an example of the angle between an optical axis of each of a first phase delaying layer and the second phase delaying layer of FIG. 4 and a transmission axis of the polarizing film. FIG. 7 is a plan view explaining another example of the angle between an optical axis of each of a first phase delaying layer and the second phase delaying layer of FIG. 4 and a transmission axis of the polarizing film.

Referring to FIGS. 1, 2, 3, 4, and 7, the optical functional layer 20 may include a polarizing layer 22 and a light control film 24. The polarizing layer 22 may include a first phase retardation film 222, a polarizing film 224, and a second phase retardation film 226. The light control film 24 may include a plurality of light-transmitting patterns 242 and a plurality of light-blocking patterns 244.

The polarizing layer 22 may polarize light transmitting through the polarizing layer 22. For example, the polarizing layer 22 may polarize light transmitting through the polarizing layer 22 so that a specific type of light is visible to a user. Specifically, the polarizing layer may polarize light incident on the display panel 10 or light emitted from the display panel 10. In an embodiment, a thickness of the polarizing layer 22 may be about 160 nm or more and about 220 nm or less. The thickness of the polarizing layer 22 may be about 160 nm or more and about 200 nm or less.

The first phase retardation film 222 may be disposed on the display panel 10. For example, the first phase retardation film 222 may be disposed between the display panel 10 and the polarizing film 224 in a cross-sectional view. In an embodiment, the first phase retardation film 222 may have a first optical axis RX1. In an embodiment, a thickness of the first phase retardation film 222 may be about 1 μm or more and about 5 μm or less. The thickness of the first phase retardation film 222 may be about 3 μm or more and about 5 μm or less.

In an embodiment, the first phase retardation film 222 may retard the phase of light transmitting the first phase retardation film 222 by ¼ wavelength. For example, the first phase retardation film 222 may be a quarter wave plate (QWP). The first phase retardation film 222 may convert linear polarization into circular polarization or elliptical polarization. In addition, the first phase retardation film 222 may convert circular polarization or elliptical polarization into linear polarization.

A polarizing film 224 may be disposed on the first phase retardation film 222. In an embodiment, the polarizing film 224 may include a poly vinyl alcohol (PVA).

The polarizing film 224 may convert light transmitted through the polarizing film 224 into linear polarization. The polarizing film 224 may include a transmission axis TMX and an absorption axis ABX. Light transmitted through the polarizing film 224 may be polarized to have a direction that is coincident with the transmission axis TMX. The polarizing film 224 may absorb light having a direction that does not coincide with the transmission axis TMX of the light transmitting the polarizing film 224.

In an embodiment, the transmission axis TMX of the polarizing film 224 and the absorption axis ABX of the polarizing film 224 may be perpendicular to each other. In an embodiment, the transmission axis TMX of the polarizing film 224 may be parallel to the first direction DR1. In other words, the transmission axis TMX of the polarizing film 224 may be parallel to the long side of the display panel 10 (e.g., the first side S1 of FIG. 2).

In an embodiment, the absorption axis ABX of the polarizing film 224 may be parallel to the second direction DR2. In an embodiment, the polarizing film 224 may be stretched in one direction. For example, the stretched direction of the polarizing film 224 may be parallel to the direction of the absorption axis ABX. In other words, the stretched direction of the polarizing film 224 may be parallel to the short side of the display panel 10 (e.g., the second side S2 of FIG. 2).

The second phase retardation film 226 may be disposed on the polarizing film 224. In an embodiment, the second phase retardation film 226 may have a second optical axis RX2. In an embodiment, a thickness of the second phase retardation film 226 may be about 1 μm or more and about 5 μm or less. Preferably, the thickness of the second phase retardation film 226 may be about 1 μm or more and about 3 μm or less. More preferably, the thickness of the second phase retardation film 226 may be about 2 μm.

In an embodiment, the second phase retardation film 226 may retard the phase of light transmitting through the second phase retardation film 226 by ½ wavelength. For example, the second phase retardation film 226 may be a half wave plate (HWP). The second phase retardation film 226 may rotate the polarization direction of linear polarization with respect to the second optical axis RX2.

The first optical axis RX1 may intersect the transmission axis TMX of the polarizing film 224 and the absorption axis ABX of the polarizing film 224 in a plan view. In an embodiment, the first optical axis RX1 may be parallel to a diagonal direction between the first direction DR1 and the second direction DR2. In another embodiment, the first optical axis RX1 may be parallel to a diagonal direction between the opposite direction of the first direction DR1 and the second direction DR2.

The second optical axis RX2 may intersect the transmission axis TMX of the polarizing film 224 and the absorption axis ABX of the polarizing film 224 in a plan view. In an embodiment, the second optical axis RX2 may be parallel to a diagonal direction between the first direction DR1 and the second direction DR2. In another embodiment, the second optical axis RX2 may be parallel to a diagonal direction between the opposite direction of the first direction DR1 and the second direction DR2.

In an embodiment, an angle formed by the first optical axis RX1 and the absorption axis ABX in a plan view may be about 400 or more and about 50° or less. Preferably, the angle between the first optical axis RX1 and the absorption axis ABX in a plan view may be about 430 or more and about 470 or less. More preferably, the angle between the first optical axis RX1 and the absorption axis ABX in a plan view may be about 45°.

In an embodiment, the angle between the second optical axis RX2 and the absorption axis ABX in a plan view may be about 400 or more and about 500 or less. Preferably, the angle between the second optical axis RX2 and the absorption axis ABX in a plan view may be about 430 or more and about 470 or less. More preferably, the angle between the second optical axis RX2 and the absorption axis ABX in a plan view may be about 45°.

In an embodiment, the first optical axis RX1 and the second optical axis RX2 may be parallel to each other. In this case, the angle between the first optical axis RX1 and the absorption axis ABX in a plan view may be substantially the same as the angle between the second optical axis RX2 and the absorption axis ABX in a plan view. For example, the first angle θ1 between the first optical axis RX1 or the second optical axis RX2 and the absorption axis ABX in a plan view may be about 400 or more and about 500 or less.

However, although the first optical axis RX1 and the second optical axis RX2 in FIG. 6 are depicted as being disposed counterclockwise in a plan view with respect to the absorption axis ABX, locations of the first optical axis RX1 and the second optical axis RX2 according to embodiments of the present disclosure may not be necessarily limited thereto, and the first optical axis RX1 and the second optical axis RX2 may also be disposed clockwise in a plan view with respect to the absorption axis ABX in a plan view.

In another embodiment, the first optical axis RX1 and the second optical axis RX2 may be symmetrical with respect to a straight line parallel to the second direction DR2 in a plan view. In this case, a size of a second angle θ2 that the first optical axis RX1 and the absorption axis ABX form with respect to each other in a plan view may be substantially a same as a third angle θ3 that the second optical axis RX2 and the absorption axis ABX form with respect to each other in a plan view. For example, the second angle θ2 that the first optical axis RX1 and the absorption axis ABX form with respect to each other in a plan view may be about 400 or more and about 50° or less. In addition, the third angle θ3 that the second optical axis RX2 and the absorption axis ABX form with respect to each other in a plan view may be about 40° or more and about 50° or less. In addition, the first optical axis RX1 may be disposed counterclockwise in a plan view with respect to the absorption axis ABX. In addition, the second optical axis RX2 may be disposed clockwise in a plan view based on the absorption axis ABX.

However, in FIG. 7, the first optical axis RX1 is disposed counterclockwise with respect to the absorption axis ABX, and the second optical axis RX2 is disposed clockwise with respect to the absorption axis ABX, but locations of the first optical axis RX1 and the second optical axis RX2 according to embodiments of the present disclosure may not be necessarily limited thereto, and the first optical axis RX1 may be disposed clockwise with respect to the absorption axis ABX, and the second optical axis RX2 may be disposed counterclockwise.

The light control film 24 may perform a function of adjusting the viewing angle of light emitted from the display panel 10. The light control film 24 may be stretched along the stretched axis. Specifically, light emitted in a direction away from the stretched direction in which the stretched axis of the light control film 24 extends may be absorbed by the light control film 24 and may not be emitted to the outside of the display device 1. In an embodiment, the light control film 24 may have a louver structure. Accordingly, the stretched direction of the light control film 24 may be referred to as a louver direction LVD.

In an embodiment, the stretched direction (e.g., a louver direction LVD) of the light control film 24 may be parallel to the first direction DR1. For example, the stretched direction of the light control film 24 may be parallel to the long side of the display panel 10. In an embodiment, the stretched direction of the light control film 24 may be perpendicular to the stretched direction of the polarizing film 224.

In an embodiment, a plurality of light-transmitting patterns 242 may be disposed between a plurality of light-blocking patterns 244. For example, a light-transmitting pattern of one of the plurality of light-transmitting patterns 242 and a light-blocking pattern of one of the plurality of light-blocking patterns 244 may be alternately arranged along the second direction DR2.

In an embodiment, each of the plurality of light-blocking patterns 244 may extend along the first direction DR1. In an embodiment, each of the plurality of light-blocking patterns 244 may be spaced apart from each other. For example, each of the plurality of light-blocking patterns 244 may be spaced apart from each other in the second direction DR2. The plurality of light-blocking patterns 244 may include a material that absorbs light or a material that reflects light. As each of the plurality of light-blocking patterns 244 extends and is spaced apart, the louver direction LVD of the light control film 24 may be defined.

In an embodiment, each of the plurality of light-blocking patterns 244 may have a tapered shape in a cross sectional view. The angle at which light emitted from the display panel 10 may transmit through the light control film 24 may be adjusted according to the inclination angle of the tapered shape. Accordingly, the viewing angle of the light emitted from the display panel 10 may be adjusted using the light control film 24. However, the structure of the light control film 24 according to the embodiments of the present disclosure may be exemplary, and may not be necessarily limited thereto, and may have various structures for adjusting the viewing angle of the light.

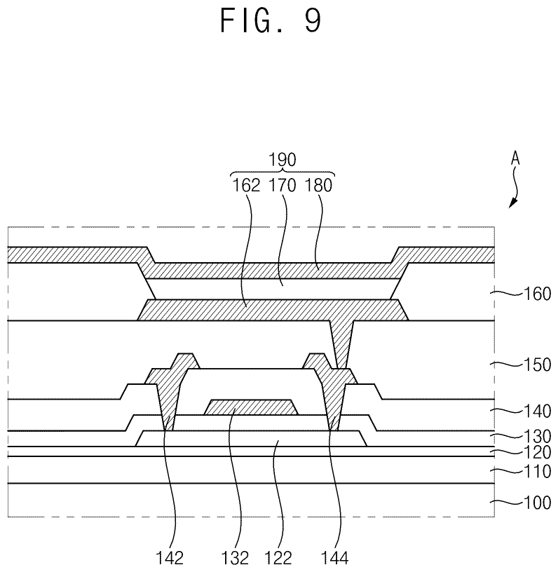

FIG. 8 is a cross-sectional view illustrating a cross-section taken along the line I-I′ of FIG. 1. FIG. 9 is a cross-sectional view illustrating an enlarged view of area A of FIG. 8. For example, FIG. 9 is an enlarged cross-sectional view illustrating a portion of the display element layer 12 in a display area DA.

Hereinafter, contents that overlap with contents described with reference to FIGS. 1, 2, 3, and 4 among stacked structures of the display device 1 described with reference to FIG. 8 will be omitted or briefly described.

Referring to FIGS. 8 and 9, the display device 1 may include a display panel 10, an optical functional layer 20, and a window layer 30. The display element layer 12 included in the display panel 10 may include a substrate 100, a first insulating layer 110, a second insulating layer 120, a transistor, a third insulating layer 130, a fourth insulating layer 140, a fifth insulating layer 150, a pixel defining layer 160, and a light-emitting element 190. The transistor may include an active pattern 122, a gate electrode 132, a first electrode 142, and a second electrode 144. The light-emitting element 190 may include a pixel electrode 162, a light-emitting layer 170, and a common electrode 180. The window layer 30 may include a light-blocking member 320 and a cover window 340.

The substrate 100 may serve as a base of the display panel 10. The substrate 100 may include a transparent material or an opaque material. The substrate 100 may include a transparent resin substrate. Examples of the transparent resin substrate include a polyimide substrate, and the like. In this case, the polyimide substrate 100 may include a first organic layer, a first barrier layer, a second organic layer, and the like. Alternatively, the substrate 100 may include a quartz substrate (e.g., a synthetic quartz substrate), a calcium fluoride substrate, a non-alkali glass substrate, and the like. These may be used alone or in combination with each other.

The first insulating layer 110 may be disposed on the substrate 100. The first insulating layer 110 may block impurities such as oxygen, moisture, and the like. from diffusing to an upper portion of the substrate 100 through the substrate 100. In addition, the first insulating layer 110 may provide a flat upper surface on an upper portion of the substrate 100. In an embodiment, the first insulating layer 110 may include an inorganic insulating material. For example, the inorganic insulating material may include silicon nitride, silicon oxide, silicon oxynitride, and the like. These may be used alone or in combination with each other.

The second insulating layer 120 may be disposed on the first insulating layer 110. The second insulating layer 120 may have a substantially flat upper surface. For example, the second insulating layer 120 may provide a substantially flat upper surface on an upper portion of the substrate 100. The second insulating layer 120 may include an inorganic insulating material. The active pattern 122 may be disposed on the second insulating layer 120. In an embodiment, the active pattern 122 may include an oxide semiconductor. For example, the oxide semiconductor may include indium (In), gallium (Ga), tin (Sn), zirconium (Zr), vanadium (V), hafnium (Hf), cadmium (Cd), germanium (Ge), chromium, titanium, zinc (Zn), and the like. These may be used alone or in combination with each other. In another embodiment, the active pattern 122 may include an organic semiconductor or a silicon semiconductor, and the like. For example, the silicon semiconductor may be polycrystalline silicon, amorphous silicon, and the like.

The active pattern 122 may include a source area, a drain area, and a channel area disposed between the source area and the drain area. In an embodiment, the source area and the drain area may be areas doped with an N-type or P-type dopant. In an embodiment, the channel area may be a non-doped area that is not doped with an N-type or P-type dopant, or may be an area doped with an N-type or P-type dopant at a relatively lower concentration than the source area and the drain area.

The third insulating layer 130 may be disposed on the active pattern 122. The third insulating layer 130 may cover the active pattern 122. The third insulating layer 130 may be a gate insulating layer of the transistor. In an embodiment, the third insulating layer 130 may have a substantially uniform thickness along the profile of the active pattern 122. However, the third insulating layer 130 according to the embodiments of the present disclosure may not be necessarily limited thereto, and the third insulating layer 130 may have a substantially flat upper surface without generating a step around the active pattern 122. In an embodiment, the third insulating layer 130 may include an inorganic insulating material.

The gate electrode 132 may be disposed on the third insulating layer 130. The gate electrode 132 may overlap the active pattern 122 in a plan view. For example, the gate electrode 132 may overlap the channel area of the active pattern 122 in a plan view. The gate electrode 132 may include a conductive material.

The fourth insulating layer 140 may be disposed on the gate electrode 132. The fourth insulating layer 140 may cover the gate electrode 132. In an embodiment, the fourth insulating layer 140 may have a substantially uniform thickness along the profile of the gate electrode 132. However, the fourth insulating layer 140 according to embodiments of the present disclosure may not be necessarily limited thereto, and the fourth insulating layer 140 may have a substantially flat upper surface without generating a step around the gate electrode 132. In an embodiment, the fourth insulating layer 140 may include an inorganic insulating material.

The first electrode 142 and the second electrode 144 may be disposed on the fourth insulating layer 140. The first electrode 142 and the second electrode 144 may be electrically connected to the active pattern 122. For example, each of the first electrode 142 and the second electrode 144 may contact the active pattern 122 through a contact hole penetrating the third insulating layer 130 and the fourth insulating layer 140 in the thickness direction (e.g., the third direction DR3).

In an embodiment, the first electrode 142 may contact the source area of the active pattern 122. When the first electrode 142 contacts the source area, the second electrode 144 may contact the drain area of the active pattern 122. Accordingly, the first electrode 142 may be referred to as the source electrode of the transistor, and the second electrode 144 may be referred to as the drain electrode of the transistor.

In another embodiment, the first electrode 142 may be referred to as the drain area of the active pattern 122. When the first electrode 142 contacts the drain area, the second electrode 144 may contact the source area of the active pattern 122. Accordingly, the first electrode 142 may be referred to as a drain electrode of the transistor, and the second electrode 144 may be referred to as a source electrode of the transistor.

The fifth insulating layer 150 may be disposed on the fourth insulating layer 140. The fifth insulating layer 150 may cover the first electrode 142 and the second electrode 144. In an embodiment, the fifth insulating layer 150 may have a substantially flat upper surface. In an embodiment, the fifth insulating layer 150 may include an organic insulating material such as polyimide (PI).

The pixel defining layer 160 may be disposed on the fifth insulating layer 150. A hole that is formed in an area corresponding to a center of the pixel electrode 162 may be defined in the pixel defining layer 160. For example, the pixel defining layer 160 may have the hole in the area corresponding to the center of the pixel electrode 162 and the pixel defining layer 160 may cover the edge of the pixel electrode 162. In an embodiment, the pixel defining layer 160 may include an organic insulating material such as polyimide (PI).

The pixel electrode 162 may be disposed on the fifth insulating layer 150. The pixel electrode 162 may contact the second electrode 144 through a contact hole that penetrates the fifth insulating layer 150 in the thickness direction (e.g., the third direction DR3). Specifically, the pixel electrode 162 may be electrically connected to the second electrode 144 through the contact hole in the fifth insulating layer 150.

In an embodiment, the pixel electrode 162 may include a conductive material such as a metal, an alloy, a transparent conductive oxide, and the like. For example, the pixel electrode 162 may include silver (Ag), indium tin oxide (ITO), and the like. In an embodiment, the pixel electrode 162 may have a multilayer structure including an indium tin oxide layer, a silver layer, and an indium tin oxide layer that are laminated in the third direction DR3. However, a structure of the pixel electrode 162 according to the embodiments of the present disclosure may not be necessarily limited thereto.

The light-emitting layer 170 may be disposed on the pixel electrode 162. For example, the light-emitting layer 170 may be disposed on the pixel defining layer 160 and on the center of the pixel electrode 162. In an embodiment, the light-emitting layer 170 may include a light-emitting material. For example, the light-emitting material may include an organic light-emitting material, a quantum dot, and the like. These may be used alone or in combination with each other. The common electrode 180 may be placed on the pixel definition film 160.

The common electrode 180 may include aluminum, platinum (Pt), silver, magnesium (Mg), gold (Au), chromium (Cr), tungsten (W), titanium, and the like. These may be used alone or in combination with each other.

The encapsulation substrate 14 may be placed on the common electrode 180. For example, the encapsulation substrate 14 may cover the light-emitting element 190. Accordingly, the encapsulation substrate 14 may block a path through which moisture or foreign substances, and the like., diffuse into the light-emitting element 190 to protect the light-emitting element 190. In an embodiment, the encapsulation substrate 14 may include a material such as quartz or glass. In another embodiment, the encapsulation substrate 14 may include at least one inorganic layer and at least one organic layer. For example, the encapsulation substrate 14 may include a first inorganic layer covering the common electrode 180, an organic layer disposed on the first inorganic layer, and a second inorganic layer disposed on the organic layer. However, a structure of the encapsulation substrate 14 according to embodiments of the present disclosure may not be necessarily limited thereto.

The adhesive layer 26 may be placed between the optical functional layer 20 and the window layer 30. The adhesive layer 26 may bind the optical functional layer 20 and the window layer 30 to each other. For example, the adhesive layer 26 is disposed on the light control film 24, and the adhesive layer 26 may bind the light control film 24 and the cover window 340 to each other. In an embodiment, the adhesive layer 26 may include a transparent adhesive material. For example, the transparent adhesive material may include an optically clear resin (OCR), an optically clear adhesive (OCA), and the like. These may be used alone or in combination.

In an embodiment, a thickness of the adhesive layer 26 may be greater than a thickness of the optical functional layer 20. For example, the thickness of the adhesive layer 26 may be about 200 μm or more and about 300 μm or less. The thickness of the adhesive layer 26 may be about 230 μm or more and about 270 μm or less. The thickness of the adhesive layer 26 may be about 250 μm.

In an embodiment, two ends of the window layer 30 may protrude outwardly relative to the two ends of each of the display panel 10 and the optical functional layer 20. However, the window layer 30 according to the embodiments of the present disclosure may not be necessarily limited thereto, and the two ends of the window layer 30 may coincide with the two ends of each of the display panel 10 and the optical functional layer 20.

The light-blocking member 320 may be disposed in the non-display area NDA. The light-blocking member 320 may block light. Accordingly, the light-blocking member 320 may prevent the components disposed under the light-blocking member 320 (e.g., the metal layers in the display panel 10) from being recognized by the user. In an embodiment, the light-blocking member 320 may include a light-blocking material. For example, the light-blocking material may include black dye, black pigment, carbon black, chrome, and the like. These may be used alone or in combination.

The cover window 340 may be disposed in the non-display area NDA and the display area DA. The cover window 340 may protect the display panel 10 and the optical functional layer 20 from external impact, scratches, impressions, and the like. In an embodiment, the cover window 340 may be ultrathin glass (UTG). For example, the window layer 30 may include soda-lime glass, alkali aluminosilicate glass, borosilicate glass, lithium aluminosilicate glass, and the like. However, the material included in the cover window 340 according to embodiments of the present disclosure may not be necessarily limited thereto, and the cover window 340 may include various materials such as plastic.

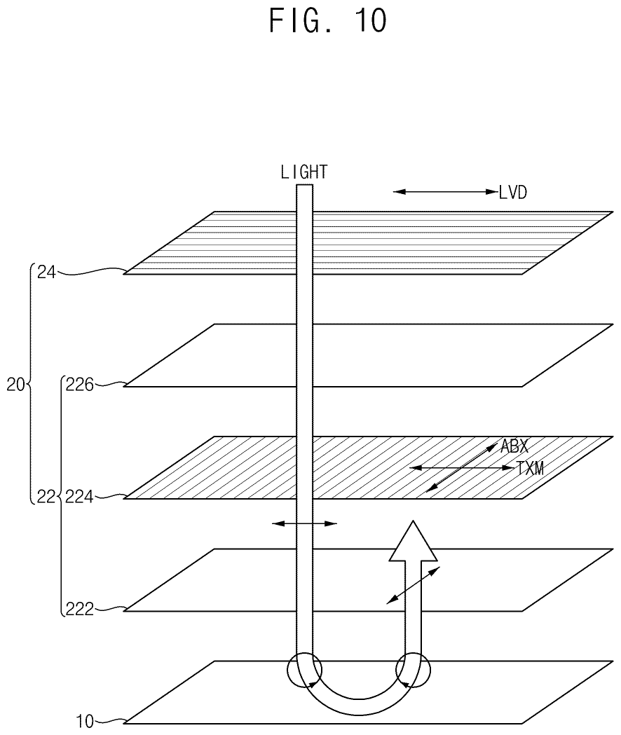

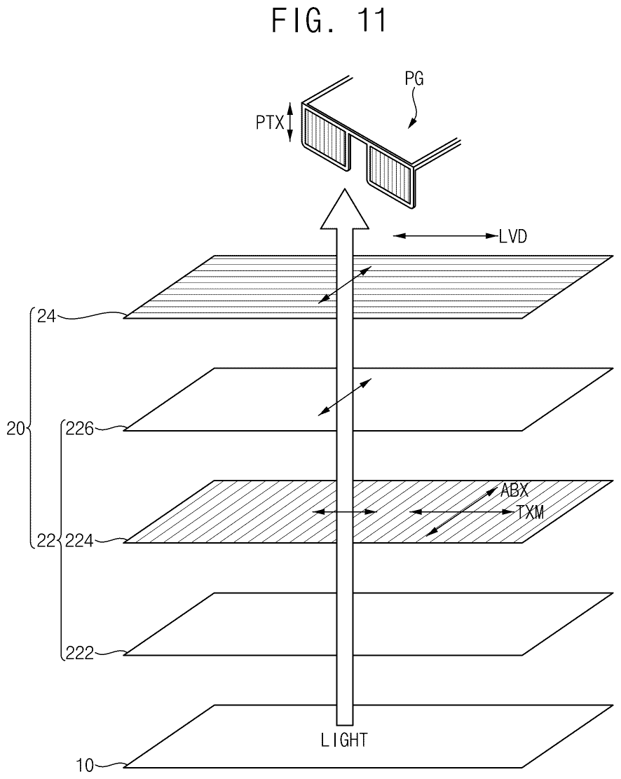

FIG. 10 is a view for explaining an example of a function of the optical functional layer of FIG. 1. FIG. 11 is a view for explaining another example of a function of the optical functional layer of FIG. 1.

For example, FIG. 10 is a view for explaining the function or role performed by the optical functional layer 20 when external light is incident on the display panel 10. In addition, FIG. 11 is a view for explaining function or role performed by the optical functional layer 20 when light is emitted from the display panel 10.

Referring to FIG. 1 and FIG. 10, when external light is incident on the window layer 30 of the display device 1, the light may sequentially transmit the light control film 24, the second phase retardation film 226, the polarizing film 224, and the first phase retardation film 222. When the light transmits the polarizing film 224, the light may be linearly polarized to coincide with the transmission axis TMX and may be incident on the first phase retardation film 222.

The light which is linearly polarized may be circularly polarized or elliptical polarized as the light passes through the first phase retardation film 222 and may be incident on the display panel 10. Specifically, the light passing through the first phase retardation film 222 may be right circularly polarized, and then a right circularly polarized light may be left circularly polarized by being reflected by the metal layers included in the display panel 10, and then a left circularly polarized light may be incident on the first phase retardation film 222. However, polarization type of the light passing through the first phase retardation film 222 according to the embodiments of the present disclosure may not be necessarily limited thereto, and when a linearly polarized light passes through the first phase retardation film 222, the linearly polarized light may be left circularly polarized.

A circularly polarized light (e.g., right circularly polarized light) may be linearly polarized so that the light is aligned with the absorption axis ABX of the polarizing film 224 when passing through the first phase retardation film 222. The light that is linearly polarized to coincide with the absorption axis ABX may be incident on the polarizing film 224 and absorbed by the polarizing film 224. Accordingly, the light incident from the outside of the display device 1 may be sequentially linearly polarized, circularly polarized, and linearly polarized, and may be finally absorbed by the polarizing film 224. Accordingly, a path through which the external light incident on the display device 1 is reflected from the display panel 10 and then emitted to the outside again may be blocked through the polarizing layer 22.

Referring to FIG. 1 and FIG. 11, when light is emitted from the display panel 10, the emitted light may transmit through the first phase retardation film 222. For example, the light emitted from the display panel 10 may be light emitted from the light-emitting element 190 of FIG. 9. The light transmitted through the first phase retardation film 222 may be incident toward the polarizing film 224. The light may be linearly polarized to coincide with the transmission axis TMX of the polarizing film 224 when the light passes through the polarizing film 224.

The linearly polarized light may be incident toward the second phase retardation film 226. The light transmitted through the second phase retardation film 226 may travel with its axis rotated to coincide with the absorption axis ABX of the polarizing film 224. The light transmitted through the second phase retardation film 226 may pass through the light control film 24. The light passing through the light control film 24 may have limited angle of emission of light. For example, when the light transmitted through the light control film 24 is dispersed close to the stretched axis of the light control film 24, the light may be transmitted through the light control film 24. In addition, if the light transmitted through the light control film 24 is dispersed away from the stretching axis of the light control film 24, the light may be absorbed by the light control film 24.

The light transmitted through the light control film 24 may reach the polarizing glasses PG worn by the user. A polarizing axis PTX of the polarizing glasses PG and the axis of the light transmitted through the light control film 24 may coincide. For example, the polarizing axis PTX of the polarizing glasses PG may coincide with the axis of linear polarization whose axis is rotated by the second phase retardation film 226. Specifically, the polarizing axis PTX of the polarizing glasses PG may coincide with the absorption axis ABX of the polarizing film 224. Accordingly, the light emitted from the display panel 10 may reach the user wearing the polarizing glasses PG. Accordingly, the user may observe an image generated by the light emitted from the display panel 10. That is, a private mode of the display device 1 may be easily implemented through the polarizing layer 22 and the light control film 24.

Meanwhile, in a conventional display device, an absorption axis of a polarizing film is parallel to the long side of the display panel, and a stretched direction of the light control film disposed on the polarizing film is also parallel to the absorption axis of the polarizing film. Accordingly, when heat is applied to the display device, the polarizing film shrinks along the absorption axis, which is the stretched direction of the polarizing film, and the light control film disposed on the polarizing film also shrinks along the stretched direction of the light control film. For example, the polarizing film and the light control film shrink at a temperature of about 90° C. or higher, or when a reliability test (e.g., UHAST (unbiased HAST)) is performed under reliability conditions of about 85° C. and about 85% RH, the polarizing film and the light control film shrink. Accordingly, a void is generated between the contracted light control film and the window layer, and the void is filled with bubbles, thereby lowering a reliability of the display device.

Referring further to FIG. 1 and FIG. 4, as described above, in the display device 1 of FIG. 1, the absorption axis ABX of the polarizing film 224 may be parallel to the short side (e.g., the second side S2) of the display panel 10. Accordingly, when heat is applied to the display device 1, the polarizing film 224 does not shrink along the long side (e.g., the first side S1) of the display panel 10, so that the phenomenon of bubbles being generated between the window layer 30 and the light control film 24 may be prevented. Accordingly, the reliability of the display device 1 may be improved.

In addition, in the display device 1, a second phase retardation film 226 that retards the phase of the transmitted light by ½ wavelength may be disposed between the polarizing film 224 and the light control film 24 in a cross-sectional view. Accordingly, even if the absorption axis ABX of the polarizing film 224 and the stretched direction of the light control film 24 do not coincide with each other, light emitted from the display panel 10 may be linearly polarized to coincide with the axis of the polarizing glasses, thereby providing an image that may be viewed by a user wearing polarizing glasses. Accordingly, the private mode of the display device 1 may be easily implemented.

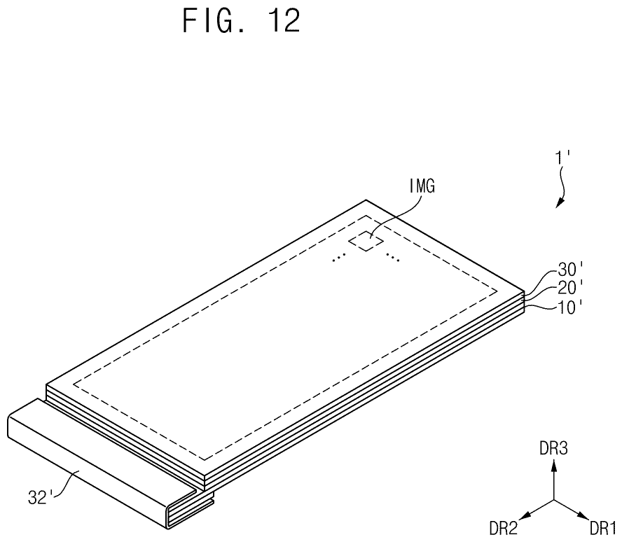

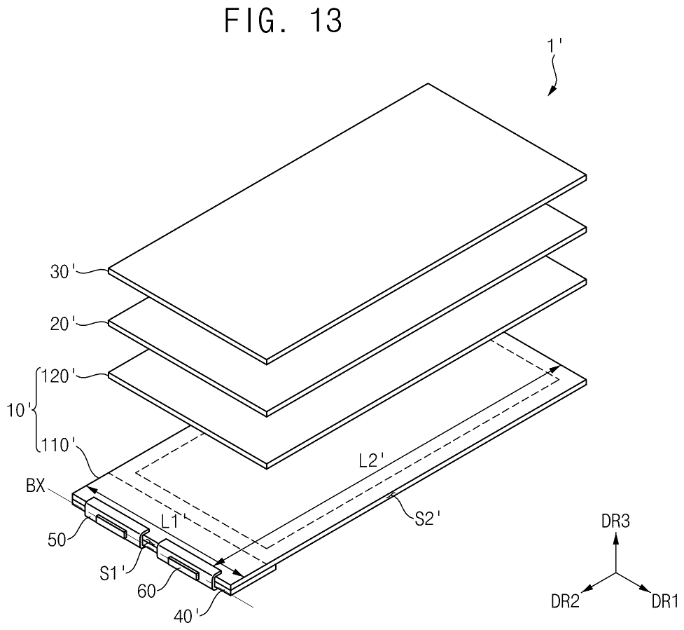

FIG. 12 is a perspective view illustrating a display device according to another embodiment of the present disclosure. FIG. 13 is an exploded perspective view illustrating an example of the display device of FIG. 12. FIG. 14 is an exploded perspective view illustrating another example of the display device of FIG. 12.

A display device 1′ described with reference to FIGS. 12 and 14 may be substantially the same as or similar to the display device 1 described with reference to FIGS. 1, 2, and 3 except for shapes of each of a display panel 10′, an optical functional layer 20′, a window layer 30′, a driving cover member 32′, and a first circuit board 40′.

Hereinafter, any content overlapping with the content described with reference to FIGS. 1, 2, and 3 will be omitted or briefly described.

Referring to FIGS. 12, 13, and 14, the display device 1′ may include a display panel 10′, an optical functional layer 20′, a window layer 30′, a driving cover member 32′, and a first circuit board 40′. Unlike the display device 1 of FIG. 1 having a structure having a long side extending horizontally and a short side extending vertically, the display device 1′ of FIG. 12 may have a structure having a short side extending horizontally and a long side extending vertically.

In an embodiment, the display panel 10′ may include a first side S1′ and a second side S2′. The first side S1′ may be a side parallel to a first direction DR1 of the display panel 10′, and the second side S2′ may be a side parallel to a second direction DR2 of the display panel 10′. A first length L1′ of the first side S1′ may be relatively smaller than a second length L2′ of the second side S2′. In other words, the first side S1′ may be a short side of the display panel 10′, and the second side S2′ may be a long side of the display panel 10′.

Depending on a shape of the display panel 10′, the optical functional layer 20′, the window layer 30′, and the first circuit board 40′ may each have a length parallel to the first direction DR1 relatively shorter than a length parallel to the second direction DR2. In addition, the length of the driving cover member 32′ of FIG. 14 in the first direction DR1 may be relatively shorter than the length of the driving cover member 32 of FIG. 1 in the first direction DR1.

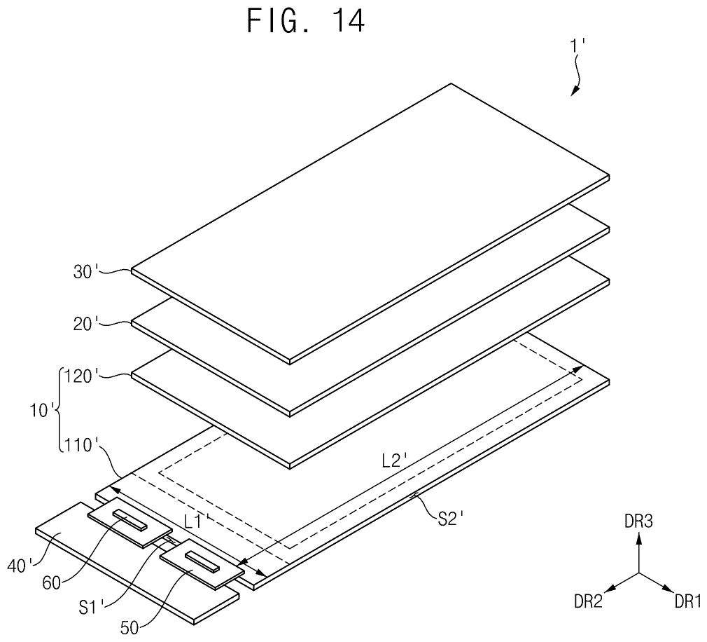

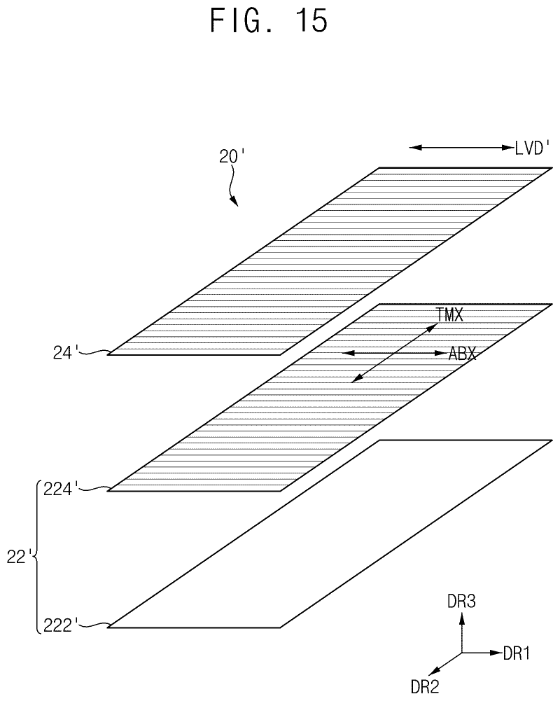

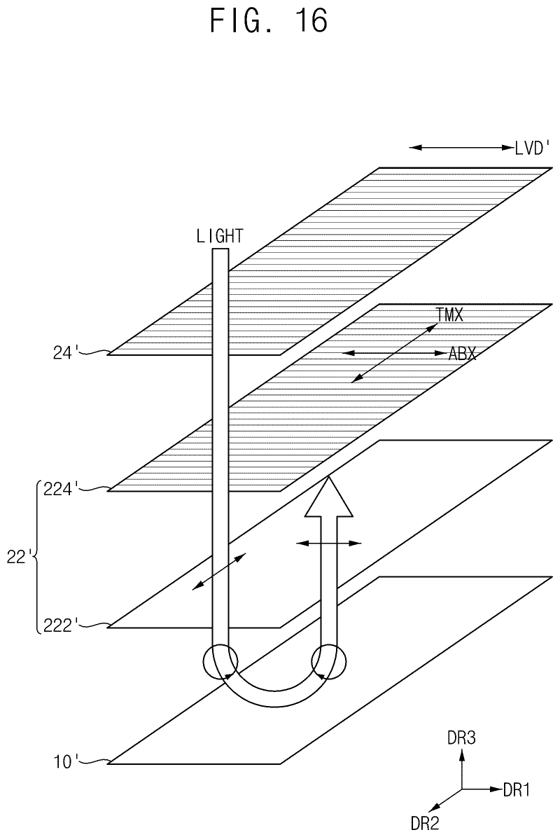

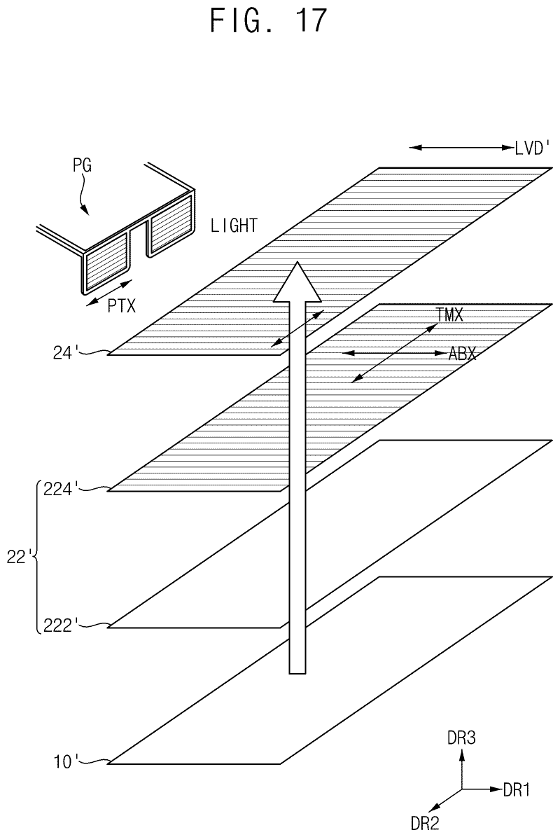

FIG. 15 is an exploded perspective view illustrating an optical functional layer of FIG. 12. FIG. 16 is a view for explaining an example of a function of the optical functional layer of FIG. 12. FIG. 17 is a view for explaining another example of a function of the optical functional layer of FIG. 12.

The optical functional layer 20′ described with reference to FIGS. 15, 16, and 17 may perform functions or roles substantially the same as or similar to the external light-blocking function and polarizing function of the optical functional layer 20 described with reference to FIGS. 4, 5, 6, and 7, and FIGS. 10 and 11, except for the shape of the optical functional layer 20, the laminated structure included in the optical functional layer 20, and the stretched direction of the light control film 24.

Hereinafter, any content overlapping with the content described with reference to FIGS. 4, 5, 6, and 7, and FIGS. 10 and 11 may be omitted or briefly described.

Referring to FIGS. 12 and 15, the optical functional layer 20′ may include a polarizing layer 22′ and a light control film 24′. The polarizing layer 22′ may include a phase retardation film 222′ and a polarizing film 224′. The polarizing layer 22′ of FIG. 15 may have a structure in which the second phase retardation film 226 is not included in the polarizing layer 22 of FIG. 4. In addition, a thickness of the polarizing layer 22′ of FIG. 15 may be relatively thinner than a thickness of the polarizing layer 22 of FIG. 4. The phase retardation film 222′ of FIG. 15 may perform substantially the same function or role as the first phase retardation film 222 of FIG. 4. In this specification, the phase retardation film 222′ may be referred to as the first phase retardation film.

In an embodiment, the phase retardation film 222′ may be disposed between the display panel 10′ and the polarizing film 224′ in a cross-sectional view. In an embodiment, the phase retardation film 222′ may have an optical axis. In an embodiment, a thickness of the phase retardation film 222′ may be about 1 μm or more and about 5 μm or less. The thickness of the phase retardation film 222′ may be about 3 μm or more and about 5 μm or less.

In an embodiment, the phase retardation film 222′ may retard the phase of light transmitting through the phase retardation film 222′ by ¼ wavelength. For example, the phase retardation film 222′ may be a quarter wave plate (QWP). The phase retardation film 222′ may convert linear polarization into circular polarization or elliptical polarization. In addition, the phase retardation film 222′ may convert circular polarization or elliptical polarization into linear polarization.

The polarizing film 224′ may convert light transmitting through the polarizing film 224′ into linear polarization. The polarizing film 224′ may include a transmission axis TMX and an absorption axis ABX. The transmission axis TMX of the polarizing film 224′ may be parallel to the second direction DR2. In other words, the transmission axis TMX of the polarizing film 224′ may be parallel to the long side (e.g., the second side S2′ of FIG. 13) of the display panel 10′.

In an embodiment, the absorption axis ABX of the polarizing film 224′ may be parallel to the first direction DR1. In an embodiment, the polarizing film 224′ may be stretched in one direction. For example, the stretched direction of the polarizing film 224′ may be parallel to the direction of the absorption axis ABX. In other words, the stretched direction of the polarizing film 224′ may be parallel to the short side (e.g., the first side S1′ of FIG. 13) of the display panel 10′.

In an embodiment, the angle between the optical axis of the phase retardation film 222′ and the absorption axis ABX of the polarizing film 224′ in a plan view may be about 400 or more and about 500 or less. The angle between the optical axis of the phase retardation film 222′ and the absorption axis ABX of the polarizing film 224′ in a plan view may be about 430 or more and about 470 or less. The angle between the optical axis of the phase retardation film 222′ and the absorption axis ABX of the polarizing film 224′ in a plan view may be about 45°.

The light control film 24′ may be disposed on the polarizing film 224′. The light control film 24′ may be stretched along the stretching axis. The stretched direction in which the stretching axis of the light control film 24′ extends may be referred to as a louver direction LVD′. In an embodiment, the stretched direction (e.g., the louver direction LVD′) of the light control film 24′ may be parallel to the first direction DR1. For example, the stretched direction of the light control film 24′ may be parallel to the short side of the display panel 10′. In an embodiment, the stretched direction of the light control film 24′ may be parallel to the stretched direction of the polarizing film 224′.

The light control film 24′ may include a plurality of light-blocking patterns extending in the first direction DR1, which is the short side direction of the display panel 10′, and light-transmitting patterns disposed between the plurality of light-blocking patterns. Each of the plurality of light-blocking patterns may be spaced apart from each other in the second direction DR2 which is the long side direction of the display panel. The louver direction LVD′ of the light control film 24′ may be defined as a stretched direction of light control film 24′.

The second phase retardation film 226 in FIG. 4 may not be disposed between the polarizing film 224′ and the light control film 24′. Specifically, when a stretched direction of the polarizing film 224′ and a stretched direction of the light control film 24′ are parallel to a direction of the short side of the display panel 10′, the second phase retardation film that rotates the axis of light may no longer be disposed between the polarizing film 224′ and the light control film 24′.

Referring to FIG. 12 and FIG. 16, when light from the outside is incident toward the window layer 30′ of the display device 1′, the light may sequentially transmit the light control film 24′, the polarizing film 224′, and the phase retardation film 222′. When the light transmits through the polarizing film 224′, the light may be linearly polarized to coincide with the transmission axis TMX and may be incident on the phase retardation film 222′.

The linearly polarized light may be circularly polarized or elliptical polarized as it transmits through the phase retardation film 222′ and may be incident on the display panel 10′. Specifically, the light transmitted through the phase retardation film 222′ may be right circularly polarized, and then the light may be left circularly polarized by being reflected by the metal layers included in the display panel 10′, and then a left circularly polarized light may be incident on the phase retardation film 222′. However, polarization type of the light transmitted through the phase retardation film 222′ according to the embodiments of the present disclosure may not be necessarily limited thereto, and when the linearly polarized light transmits through the phase retardation film 222′, the light may be left circularly polarized.

Circularly polarized light (e.g., right circularly polarization light) may be transmitted through the phase retardation film 222′ and linearly polarized so that the light passing through the phase retardation film 222′ may have polarization axis the same as the absorption axis ABX of the polarizing film 224′, thus all the light passing through the phase retardation film 222′ may be absorbed by the polarizing film 224′. Accordingly, light incident from the outside of the display device 1′ may be sequentially linearly polarized, circularly polarized, and linearly polarized, and may be finally absorbed by the polarizing film 224′. Accordingly, a path of the external light incident on the display device 1′ being reflected from the display panel 10′ and then emitted to the outside again may be blocked through the polarizing layer 22′.

Referring to FIG. 12 and FIG. 17, when light is emitted from the display panel 10′, the emitted light may be transmitted through the phase retardation film 222′. For example, the light emitted from the display panel 10′ may be light emitted from the light-emitting element 190 of FIG. 9. The light transmitted through the phase retardation film 222′ may be incident on the polarizing film 224′. The light may be linearly polarized to coincide with the transmission axis TMX of the polarizing film 224′ as the light transmits through the polarizing film 224′.

The linearly polarized light may be incident on the light control film 24′. The light passing through the light control film 24′ may have limited angle of emission of light. For example, when the light transmitted through the light control film 24′ is dispersed close to the stretched axis of the light control film 24′, the light may be transmitted through the light control film 24′. In addition, if the light transmitted through the light control film 24′ is dispersed away from the stretched axis of the light control film 24′, the light may be absorbed by the light control film 24′.

The light transmitted through the light control film 24′ may reach the polarizing glasses PG worn by the user. The polarizing axis PTX of the polarizing glasses PG and the axis of the light transmitted through the light control film 24′ may coincide. For example, the polarizing axis PTX of the polarizing glasses PG may coincide with the axis of the linear polarization polarized by the polarizing film 224′. Specifically, the polarizing axis PTX of the polarizing glasses PG may coincide with the transmission axis TMX of the polarizing film 224′. Accordingly, the light emitted from the display panel 10′ may reach the user wearing the polarizing glasses PG. Accordingly, the user may observe an image generated by the light emitted from the display panel 10′. That is, a private mode of the display device 1′ may be easily implemented through the polarizing layer 22′ and the light control film 24′.

As described above, referring to FIG. 12 and FIG. 15, as described above, in the display device 1′ of FIG. 12, the absorption axis ABX of the polarizing film 224′ may be parallel to the short side (e.g., the first side S1′) of the display panel 10′. Accordingly, when heat is applied to the display device 1′, the polarizing film 224′ does not shrink along the long side (e.g., the second side S2′) of the display panel 10′, so that the phenomenon of bubbles being generated between the window layer 30′ and the light control film 24′ may be prevented. Accordingly, a reliability of the display device 1′ may be improved.

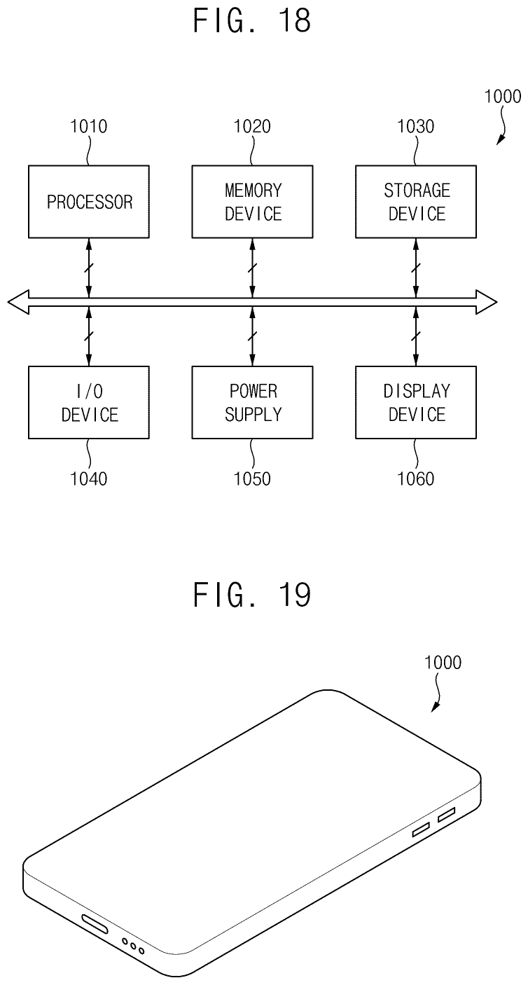

FIG. 18 is a block diagram illustrating an electronic device according to an embodiment of the present disclosure. FIG. 19 is a view for explaining an example of the electronic device of FIG. 18 implemented as a smartphone. FIG. 20 is a view for explaining an example of the electronic device of FIG. 18 implemented as a television.

Referring to FIGS. 18, 19, and 20, the electronic device 1000 may include a processor 1010, a memory device 1020, a storage device 1030, an input/output device 1040, a power supply 1050, and a display device 1060. The display device 1060 included in the electronic device 1000 may be the display device 1 of FIG. 1 or the display device 1′ of FIG. 12. In addition, the electronic device 1000 may further include several ports that may communicate with a video card, a sound card, a memory card, a USB device, or the like, or may communicate with other systems.

The processor 1010 may perform specific calculations or tasks. According to an embodiment, the processor 1010 may be a microprocessor, a central processing unit, an application processor, or the like. The processor 1010 may be connected to other components via an address bus, a control bus, a data bus, and the like According to an embodiment, the processor 1010 may also be connected to an expansion bus, such as a Peripheral Component Interconnect (PCI) bus. The processor 1010 may output data control signals and image data to a timing controller included in the first circuit board 40 of FIG. 2.

The memory device 1020 may store data necessary for the operation of the electronic device 1000. For example, the memory device 1020 may include a nonvolatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and/or a volatile memory device such as a dynamic random access memory (DRAM) device, a static random access memory (SRAM) device, a mobile DRAM device, and the like.

The storage device 1030 may include a solid-state drive (SSD), a hard disk drive (HDD), a CD-ROM, and the like The input/output device 1040 may include input means such as a keyboard, a keypad, a touchpad, a touchscreen, a mouse, and the like, and output means such as a speaker, a printer, and the like According to an embodiment, a display device 1060 may be included in the input/output device 1040. The power supply 1050 may supply power necessary for the operation of the electronic device 1000. The display device 1060 may be connected to other components through the buses or other communication links.

In an embodiment, as illustrated in FIG. 19, the electronic device 1000 may be implemented as a smartphone. In another embodiment, as illustrated in FIG. 20, the electronic device 1000 may be implemented as a television. However, this is exemplary, and the electronic device 1000 according to embodiments of the present disclosure may not be limited thereto. For example, the electronic device 1000 may be implemented as a mobile phone, a video phone, a smart pad, a smart watch, a tablet PC, a vehicle display, a computer monitor, a notebook computer, a head-mounted display device, and the like In addition, the electronic device 1000 may be a television, a monitor, a notebook computer, or a tablet. In addition, the electronic device 1000 may be an automobile.

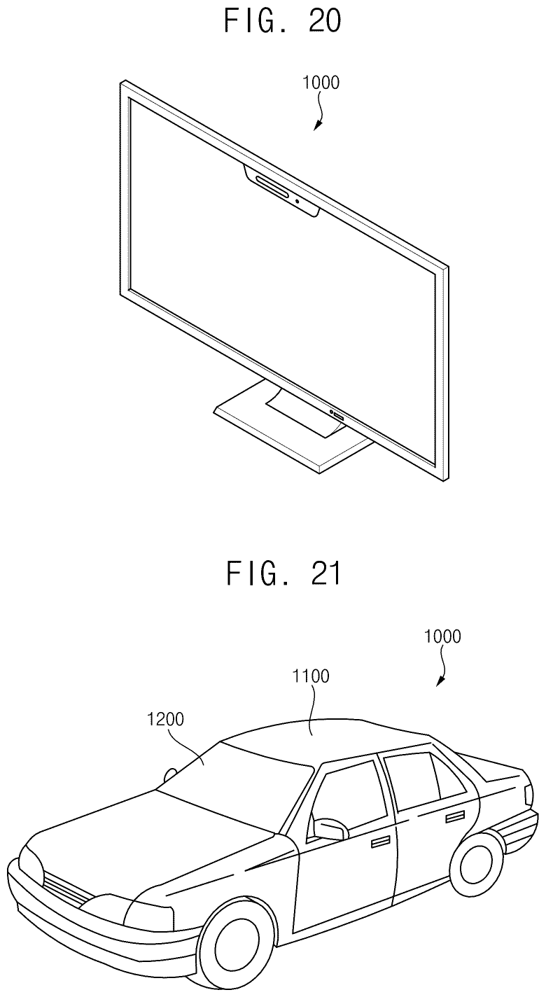

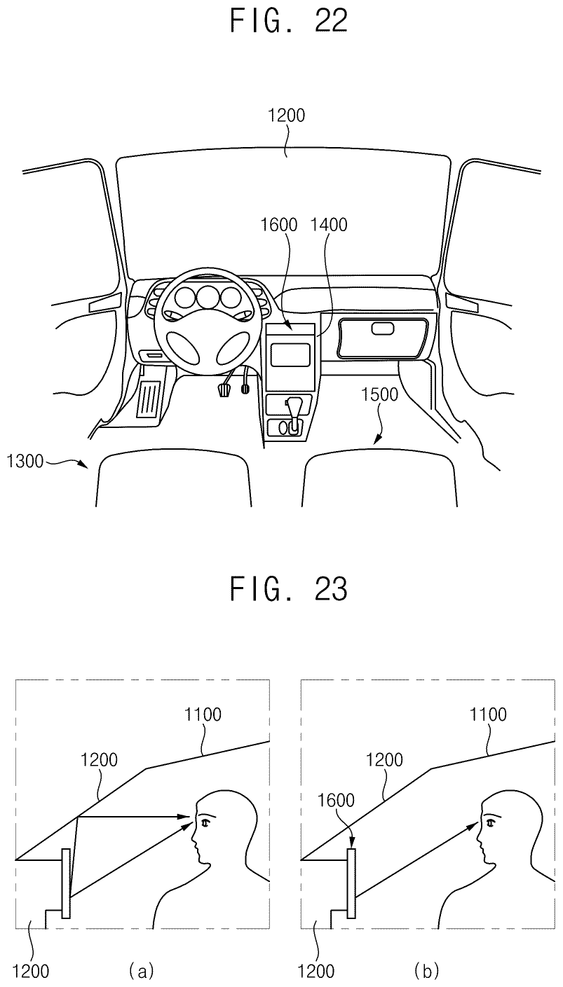

FIG. 21 is a view illustrating an example of the electronic device of FIG. 18 implemented as an automobile. FIG. 22 is a view illustrating an interior of the automobile of FIG. 21.

Referring to FIGS. 18, 21, and 22, an automobile 1000 may include a body 1100, a windshield 1200, a driver's seat 1300, a dashboard 1400, a passenger seat 1500, and a display device 1600. The display device 1600 may be the display device 1 of FIG. 1, the display device 1′ of FIG. 12 or the display device 1060 of FIG. 18.

The body 1100 may form the exterior of the automobile 1000 and define an interior space in which the driver and passengers ride. The body 1100 may protect the driver and passengers from the outside. The windshield 1200 may include a transparent or translucent material to secure a forward view of the driver and passengers. The windshield 1200 according to embodiments of the present invention is not necessarily limited thereto. The windshield 1200 may be a display device that displays an image.

The driver's seat 1300 may provide a space for accommodating the driver. The driver's seat 1300 may include driving equipment for driving the automobile 1000. For example, the driving equipment may include a steering wheel, a brake device, an accelerator device, and the like. The dashboard 1400 may have components that implement various functions for the driver and the passenger arranged thereon. The components may implement audio functions, heaters, or cooling functions, and the like. according to the operations of the driver and the passenger. The passenger seat 1500 may be positioned adjacent to the driver's seat 1300 and may provide a space for accommodating the passenger.

A vehicle display device 1600 may be disposed on the dashboard 1400. The display device 1600 may emit light to display an image. For example, the display device 1600 may be a device for displaying a user interface that provides driving information, speed information, entertainment information, and the like. to the driver and the passenger. The display device 1600 may include the optical functional layer 20 of FIG. 1. Accordingly, the light emitted from the display device 1600 may be polarized, and the light may be absorbed or transmitted so that only light having a specific viewing angle is recognized, thereby selectively transmitting the image to the driver and the passenger.

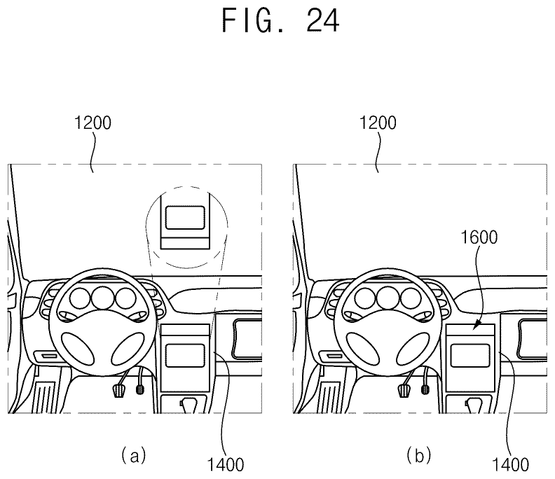

FIGS. 23 and 24 are views for explaining an effect of the display device included in the automobile of FIG. 21.

For example, FIG. 23(a) and FIG. 24(a) are views for explaining light emitted from a display device of the automobile 1000 that does not include the light control film 24 of FIG. 4 and/or the light control film 24′ of FIG. 15. In addition, FIG. 23(b) and FIG. 24(b) are views for explaining light emitted from a display device 1060 of the automobile 1000 that includes the light control film 24 of FIG. 4 and/or the light control film 24′ of FIG. 15.

Referring to FIG. 4, FIG. 15, and FIGS. 21, 22, 23, and 24, as illustrated in FIG. 23(a) and FIG. 24(a), light emitted from a display device that does not include the light control film 24, 24′ and includes the polarizing layer 22, 22′ may be reflected by the front windshield 1200 so that an image may be recognized by a driver or a passenger. Specifically, since the light emitted from the display device is not subject to a viewing angle adjustment, the driver or the passenger can observe an image generated by the light through the windshield 1200.

As illustrated in FIG. 23(b) and FIG. 24(b), the light emitted from the display device 1600 including the polarizing layer 22, 22′ and the light control film 24, 24′ may not be reflected on the windshield 1200. Accordingly, the driver or the passenger may not observe an image reflected by the windshield 1200. Specifically, since the light emitted from the display device 1600 is subject to a viewing angle adjustment by the light control film 24, 24′, the image generated by the light may not be displayed on the windshield 1200. Accordingly, when the driver or a passenger drives or assists driving through the vehicle 1000, the driver or the passenger may not be disturbed by the display device 1600 and may drive safely.

The device according to the embodiments may be applied to a display device included in a computer, a notebook, a mobile phone, a smartphone, a smart pad, a PMP, a PDA, an MP3 player, or the like.

Although the devices according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a display panel including at least one light-emitting element and including a first side and a second side having a length shorter than a length of the first side;
a polarizing film disposed on the display panel and including an absorption axis parallel to the second side of the display panel and a transmission axis which intersects the absorption axis;
a first phase retardation film disposed between the display panel and the polarizing film in a cross-sectional view and including a first optical axis which intersects the transmission axis of the polarizing film and the absorption axis of the polarizing film in a plan view; and
a light control film disposed on the polarizing film, and including a plurality of light-blocking patterns spaced apart from each other and a plurality of light-transmitting patterns disposed between the plurality of light-blocking patterns.

2. The display device of claim 1, wherein the first phase retardation film retards a phase of light transmitting the first phase retardation film by ¼ wavelength.

3. The display device of claim 1, wherein an angle between the first optical axis and the absorption axis is about 40° or more and about 50° or less in a plan view.

4. The display device of claim 1, wherein a thickness of the first phase retardation film is about 3 μm or more and about 5 μm or less.

5. The display device of claim 1, further comprising:
a second phase retardation film disposed between the polarizing film and the light control film in a cross-sectional view, and including a second optical axis which intersects the transmission axis of the polarizing film and the absorption axis of the polarizing film in a plan view.

6. The display device of claim 5, wherein a stretched direction of the light control film is vertical to the absorption axis of the polarizing film.

7. The display device of claim 6, wherein each of the light-blocking patterns of the light control film is spaced apart from each other in a direction parallel to the second side of the display panel, and
wherein each of the light-blocking patterns of the light control film extends along a direction parallel to the first side of the display panel.

8. The display device of claim 5, wherein the second phase retardation film retards a phase of light transmitting the second phase retardation film by ½ wavelength.

9. The display device of claim 5, wherein an angle between the second optical axis and the absorption axis is about 40° or more and about 50° or less in a plan view.

10. The display device of claim 5, wherein a thickness of the second phase retardation film is about 1 μm or more and about 3 μm or less.

11. The display device of claim 1, wherein a stretched direction of the light control film is parallel to the absorption axis of the polarizing film.

12. The display device of claim 11, wherein each of the light-blocking patterns of the light control film is spaced apart from each other in a direction parallel to the first side of the display panel, and
wherein each of the light-blocking patterns of the light control film extends along a direction parallel to the second side of the display panel.

13. A display device comprising:
a display panel including at least one light-emitting element, and including a first side extending along a first direction and a second side extending along a second direction which intersects with the first direction and having a length shorter than a length of the first side;
a polarizing film disposed on the display panel and including a transmission axis parallel to the first direction and an absorption axis parallel to the second direction;
a first phase retardation film disposed between the display panel and the polarizing film in a cross-sectional view and including a first optical axis which intersects with the transmission axis of the polarizing film and the absorption axis of the polarizing film; and
a second phase retardation film disposed on the polarizing film and including a second optical axis which intersects with the transmission axis of the polarizing film and the absorption axis of the polarizing film.

14. The display device of claim 13, wherein the first phase retardation film retards a phase of light transmitting the first phase retardation film by ¼ wavelength, and
wherein the second phase retardation film retards a phase of light transmitting the second phase retardation film by ½ wavelength.

15. The display device of claim 13, wherein an angle between the first optical axis and the absorption axis is about 40° or more and about 50° or less in a plan view, and
wherein an angle between the second optical axis and the absorption axis is about 40° or more and about 50° or less in a plan view.

16. The display device of claim 13, wherein a stretched direction of the polarizing film is parallel to the second side of the display panel.

17. The display device of claim 13, further comprising:
a light control film disposed on the second phase retardation film.

18. The display device of claim 17, wherein the light control film includes:
a plurality of light-blocking patterns extending along the first direction and spaced apart from each other in the second direction; and
a plurality of light-transmitting patterns disposed between the plurality of light-blocking patterns, and
wherein a stretched direction of the light control film is parallel to the first side of the display panel.

19. An electronic device comprising:
a display device; and
a processor configured to drive the display device,
wherein the display device includes:
a display panel including at least one light-emitting element and including a first side and a second side having a length shorter than a length of the first side;
a polarizing film disposed on the display panel and including an absorption axis parallel to the second side of the display panel and a transmission axis which intersects the absorption axis;
a first phase retardation film disposed between the display panel and the polarizing film in a cross-sectional view and including a first optical axis which intersects the transmission axis of the polarizing film and the absorption axis of the polarizing film in a plan view; and
a light control film disposed on the polarizing film, and including a plurality of light-blocking patterns spaced apart from each other and a plurality of light-transmitting patterns disposed between the plurality of light-blocking patterns.

20. The display device of claim 19, wherein the electronic device is part of one of a smart phone, a television, a mobile phone, a video phone, a smart pad, a smart watch, a tablet PC, a vehicle display, a computer monitor, a notebook computer, a head-mounted display device, a television, a monitor, a notebook computer, a tablet and an automobile.
